(19) United States
(12) Patent Application Publication
(10) Pub. No.: US 2015/0373835 A1
(43) Pub. Date: Dec. 24, 2015

(54) METHOD FOR MANUFACTURING SHIELD PRINTED WIRING BOARD, AND SHIELD FILM AND SHIELD PRINTED WIRING BOARD

(71) Applicant: TATSUTA ELECTRIC WIRE & CABLE CO., LTD., Higashiosaka-shi, Osaka (JP)

(72) Inventors: Hiroshi TAJIMA, Kizugawa-shi, Kyoto (JP); Masayoshi IWASAKI, Kizugawa-shi, Kyoto (JP); Kenji KAMINO, Kizugawa-shi, Kyoto (JP); Yusuke HARUNA, Kizugawa-shi, Kyoto (JP)

(21) Appl. No.: 14/653,917

(22) PCT Filed: Dec. 10, 2013
(86) PCT No.: PCT/JP2013/083119

§ 371 Date: Jun. 19, 2015

(30) Foreign Application Priority Data
Dec. 20, 2012 (JP) 2012-278551

(51) Int. Cl. H05K 1/02; H05K 3/04

(52) U.S. Cl. CPC H05K 1/0216; H05K 3/04

(57) ABSTRACT

A method of manufacturing a shield printed wiring board, a shield film, and a shield printed wiring board, which make it possible to achieve cost reduction, are provided. A method of manufacturing a shield printed wiring board includes the steps of: forming a shield film which includes an insulating layer formed of resin in which polymerization has proceeded so that a resin cure degree is 90% or higher, a metal layer stacked onto the insulating layer, and an adhesive layer stacked onto the metal layer; mounting the shield film on a printed board; and thermally pressing the shield film and the printed board onto each other.

### TECHNICAL FIELD

The present invention relates to a method of manufacturing a shield printed wiring board which is used in an apparatus such as an electronic device or the like, a shield film, and a shield printed wiring board.

### BACKGROUND

A shield film for shielding noise such as electromagnetic waves has been publicly known. For example, PTL 1 discloses a method of manufacturing a shield flexible printed wiring board in such a way that, when a shield film is provided on a base film including a printed circuit, a reinforcing shield film is formed by providing a shield layer on one side of a cover film and pasting an adhesive film having peelable adhesiveness on the other side of the cover film, the reinforcing shield film is mounted on the base film so that the shield layer is in contact with the base film, and the adhesive film is peeled off after the reinforcing shield film is adhered to the base film by heating and pressurization.

The cover film (insulating layer) in the known shield film above is formed by thinly applying liquid resin onto a PET (polyethylene terephthalate) film which is a base and is termed an adhesive film (protective layer). In such a cover film, the progress of polymerization typically remains in a semi-cured condition which is so-called B-stage before a thermal pressing process for thermally pressing onto the printed wiring board is conducted, i.e., as the shield film alone.

In this way, the cover film is, as the shield film alone before the thermal pressing process, highly adhesive to the adhesive film because the cover film is in the semi-cured condition, and the cover film cannot be peeled off from the adhesive film. In addition to the above, the adhesive film has a function as a base when the cover film and a metal thin film layer are stacked, a function of protecting the cover film in the thermal pressing process, and a function of protecting the cover film in the semi-cured condition when the shield film is transported or stored. On this account, in the shield film alone, the adhesive film must be stacked onto the cover film.

In the meanwhile, typically a protective member is further provided on the surface on the adhesive film side or on the surface opposite to the adhesive film of the above-described shield film, and the shield film is half-cut so that the protective member is not fully cut. As a result, the shield film which has been cut to have a desired shape is stacked on the protective member. Before the thermal pressing process, it is possible to peel this shield film off from the protective member and mount the shield film on the printed wiring board.

### CITATION LIST

### Patent Literature

[PTL 1] Japanese Unexamined Patent Publication No. 2000-269632

### SUMMARY OF THE INVENTION

### Technical Problem

However, when the shield printed wiring board is manufactured by a known method such as the method recited in PTL 1, after the adhesiveness between the adhesive film and the cover film is lowered by curing the cover film by means of thermal pressing onto the printed board, it is required to peel the adhesive film off from the cover film. A step of peeling the adhesive film off from the shield film crimped onto the printed board is therefore necessary. Furthermore, because shield films are recently downsized together with the downsizing of printed boards on which the shield films are crimped, the step of peeling the adhesive film off from the shield film crimped onto the printed board takes time and labor, and leads to an increase in cost.

Furthermore, the known method is disadvantageous in that, after the adhesive film made of PET is pressed at a high temperature (e.g., 200 degrees centigrade), for a long time, or plural times, PET is deteriorated and the adhesive film cannot be peeled off.

An object of the present invention is to provide a method of manufacturing a shield printed wiring board, a shield film, and a shield printed wiring board, which make it possible to achieve cost reduction.

### Solution to Problem

A method of manufacturing a shield printed wiring board of the present invention is characterized by including the steps of: forming a shield film which includes an insulating layer formed of resin in which polymerization has proceeded so that a resin cure degree is 90% or higher, a shield layer stacked onto the insulating layer, and an adhesive layer stacked onto the shield layer; mounting the shield film on a printed board; and thermally pressing the shield film and the printed board onto each other.

In this arrangement, the insulating layer is made of resin in which polymerization has proceeded so that the resin cure degree is 90% or higher. With this, the insulating layer in the cured state has functions of known protective layers such as a function as a base on which a conductive layer is stacked, and hence no protective layer is required as a shield film. As a result, it is unnecessary to execute a process for peeling the protective layer off from the shield film of the shield printed wiring board after the thermal pressing process, and hence cost reduction is achieved.

In addition to the above, in the method of manufacturing the shield printed wiring board of the present invention, the step of forming the shield film may include: a half-cutting process for cutting, from the adhesive layer side, the shield film which is stacked onto the protective member such that a surface on the insulating layer side of the shield film is in contact with the protective member, without fully cutting the protective member; and a process for peeling the shield film, which has been cut, off from the protective member.

According to this arrangement, the shield film stacked on the protective member is half-cut, and the shield film having been cut is peeled off and mounted on the printed board. This makes it possible to form a shield film having a shape suitable for a printed board, and such a shield film can be stored on the protective member.

In addition to the above, in the method of manufacturing the shield printed wiring board of the present invention, the step of forming the shield film may include a cutting process for cutting the shield film which is mounted on a protective sheet (e.g., sheet-shaped rubber or resin) so that a surface on the insulating layer side of the shield film is in contact with the protective sheet.

According to the arrangement above, the shield film is cut on the protective sheet, and the shield film having been cut is mounted on the printed wiring board. This makes it possible to form a shield film having a shape suitable for a printed board.

In addition to the above, in the method of manufacturing the shield printed wiring board of the present invention, the insulating layer may be formed to be film-shaped.

According to this arrangement, the insulating layer is formed to be film-shaped. Because such an insulating layer is highly flexible, breakage of the insulating layer is unlikely to occur when the insulating layer is thermally pressed onto a printed wiring board with irregularities.

In addition to the above, in the method of manufacturing the shield printed wiring board of the present invention, the insulating layer may be formed of heat-resistant resin.

According to this arrangement, because the insulating layer is formed of heat-resistant resin, the resistance in the thermal pressing process is improved.

In addition to the above, in the method of manufacturing the shield printed wiring board of the present invention, the insulating layer may be formed to be 2 μm to 25 μm in thickness. According to the arrangement above, because the layer thickness is arranged to be 2 μm to 25 μm, the embeddedness of the adhesive layer of the shield film in the printed board is improved in the thermal pressing process.

In addition to the above, a shield film of the present invention is characterized by including: an insulating layer formed of resin in which polymerization has proceeded so that a resin cure degree is 90% or higher; a shield layer stacked onto the insulating layer; and an adhesive layer stacked onto the shield layer.

In this arrangement, the insulating layer is made of resin in which polymerization has proceeded so that the resin cure degree is 90% or higher. With this, the insulating layer in the cured state has functions of known protective layers such as a function as a base on which a conductive layer is stacked, and hence no protective layer is required as a shield film. As a result, it is unnecessary to execute a process for peeling the protective layer off from the shield film of the shield printed wiring board after the thermal pressing process, and hence cost reduction is achieved.

In addition to the above, in the shield film of the present invention, the insulating layer may be formed to be film-shaped.

According to this arrangement, the insulating layer is formed to be film-shaped. Because such an insulating layer is highly flexible, breakage of the insulating layer is unlikely to occur when the insulating layer is thermally pressed onto a printed wiring board with irregularities.

In addition to the above, in the shield film of the present invention, the insulating layer may be formed of heat-resistant resin.

According to this arrangement, because the insulating layer is formed of heat-resistant resin, the resistance in the thermal pressing is improved.

In addition to the above, in the shield film of the present invention, the insulating layer may be formed to be 2 μm to 25 μm in thickness.

According to the arrangement above, because the layer thickness is arranged to be 2 μm to 25 μm, the embeddedness of the adhesive layer of the shield film in the printed board is improved in the thermal pressing process.

In addition to the above, a shield printed wiring board of the present invention is characterized by being formed by thermally pressing the shield film above and a printed wiring board onto each other.

### BRIEF DESCRIPTION OF THE DRAWINGS

FIG. 1 shows a shield film.

FIG. 2 shows the shield film before it is cut.

FIG. 3 illustrates a half-cutting process for half-cutting the shield film.

FIG. 4 shows a state in which the shield film which has been half-cut is provided on a protective member.

FIG. 5 illustrates a cutting process for cutting the shield film.

FIG. 6 shows a thermal pressing process for thermally pressing the shield film onto a printed board.

FIG. 7 shows a shield printed wiring board.

### PREFERRED EMBODIMENT OF INVENTION

The following will describe a preferred embodiment of the present invention with reference to figures.

### (Configuration of Shield Film 1)

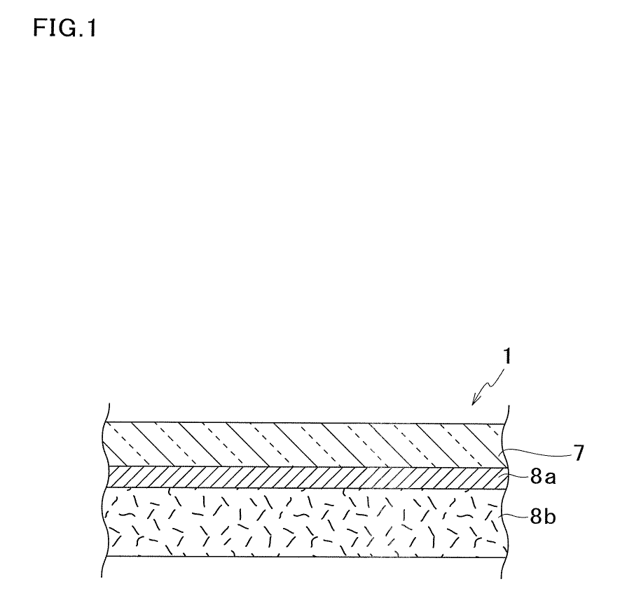

As shown in FIG. 1, the shield film 1 includes an insulating layer 7 which is made of resin in which polymerization has proceeded so that a resin cure degree becomes 90% or higher, a metal layer 8a which is a shield layer and is stacked on the insulating layer, and an adhesive layer 8b which is stacked on the metal layer 8a.

The resin cure degree above indicates the degree (reaction rate) of progress of curing reaction of resin. The resin cure degree of a non-reacted material is 0%, whereas the resin cure degree of a reacted material is 100%. The resin cure degree is, for example, obtained from a value of the resin cure degree measured based on a FT-IR (Fourier transform type infrared) spectrum. Infrared light is applied to target resin by a FT-IR device, and a spectrum is obtained by transmission or diffraction. In this way, the progress of the curing reaction can be measured. To be more specific, a non-reacted material and a fully-reacted material are compared with each other in the spectrum of resin, and a range where the most conspicuous difference is observed is specified. The peak intensities of the non-reacted material, the fully-reacted material, and a measurement target resin in that range are compared with one another, and a resin cure degree of the measurement target resin is determined.

The measurement of the resin cure degree may not be done based on the FT-IR, and may be done by using a dispersive infrared spectrophotometer or the like.

Although not illustrated in FIG. 1, the shield film 1 may be pasted onto a protective member before a thermal pressing process for thermally pressing the shield film 1 onto a printed board or the like.

### (Insulating Layer 7)

The insulating layer 7 is formed of resin in which polymerization has proceeded so that the resin cure degree is 90% or higher. The method of curing is thermosetting, ultraviolet curing, electron beam curing, or the like, and any method is employed as long as the polymerization proceeds and curing is achieved. Examples of the thermosetting resin include phenol resin, acrylic resin, epoxy resin, melamine resin, silicon resin, and acryl-modified silicon resin. Examples of the ultraviolet curing resin include epoxy acrylate resin, polyester acrylate resin, and methacrylate modifications thereof.

The insulating layer 7 is preferably formed of heat-resistant resin, e.g., polyimide. This allows the insulating layer 7 to endure thermal pressing conducted plural times or for a long time. Furthermore, thermoplastic polyimide having a lower water absorption rate than polyimide is more preferable. This prevents the swelling of the insulating layer in, for example, a process of reflow to the shield printed wiring board.

The insulating layer 7 may not be formed of the resin above, and may be formed of heat-resistant resin such as polypropylene, cross-linked polyethylene, polyester, polybenzimidazole, aramid, polyimidoamide, polyetherimide, polyphenylene sulfide (PPS), and polyethylene naphthalate (PEN).

The insulating layer 7 is preferably formed of film-shaped insulating resin. The insulating layer 7 is highly flexible in this case. On this account, when the insulating layer 7 is thermally pressed onto a printed wiring board with irregularities, breakage of the insulating layer 7 is unlikely to occur because the insulating layer 7 is easily deformed in accordance with the irregularities. The insulating layer 7 may not be film-shaped insulating resin, and may be a coating layer which is formed by coating insulating resin onto a film which is a base. Even if the insulating layer 7 is formed of such a coating layer, the film which is the base can be peeled off at room temperatures before the thermal pressing onto the printed wiring board. It is therefore possible to produce a shield film from which a protective layer has been peeled off before thermal pressing, and hence a process for peeling the protective layer off from the shield printed wiring board after the thermal pressing is unnecessary.

The lower limit of the thickness of the insulating layer 7 is preferably 2 μm, and more preferably 4 μm. The upper limit of the thickness of the insulating layer 7 is preferably 25 μm, and even more preferably 8 μm.

The insulating layer 7 may include a coloring pigment or the like in the above-described resin. An example of the coloring pigment is carbon black. The outer surface of the insulating layer 7 may be matted. The matting is performed by a method such as emboss rolling, kneading matting, chemical matte coating, and sand blasting.

The insulating layer 7 may be constituted by plural layers instead of a single layer. For example, the insulating layer 7 may have a two-layer structure formed by serially providing a hard layer which is formed of resin excelling in abrasion resistance and blocking resistance and a soft layer which is formed of resin excelling in cushioning property.

(Metal Layer 8a)

The metal layer 8a is preferably formed by rolling. This allows the shield film 1 to have good shape retaining property and good flexibility when the shield film 1 is thermally pressed onto a printed wiring board with irregularities. The metal layer 8a is not limited to this arrangement, and may be a metal thin film formed by vacuum deposition, electroplating, electroless plating, sputtering, electron-beam evaporation, vacuum deposition, chemical vapor deposition, metal organic chemical vapor deposition, or the like.

Alternatively, the metal layer 8a may be a metal thin film formed by special electroplating to have a configuration in which crystals spread in in-plane directions in the same manner as metal foils. Good shape retaining property is obtained by this as in the case of rolling.

Examples of the metal material of which the metal layer 8a is formed include nickel, copper, silver, tin, gold, palladium, aluminum, chromium, titanium, zinc, and an alloy including at least one of these materials. The metal layer 8a is preferably formed of silver in particular. With this, a sufficient shield property is obtained even if the layer is thin.

The lower limit of the thickness of the metal layer 8a is preferably 0.01 μm, and more preferably 0.1 μm. The upper limit of the thickness of the metal layer 8a is preferably 18 μm, more preferably 12 μm, and even more preferably 6 μm. The metal layer 8a may be formed of plural layers instead of a single layer.

(Adhesive Layer 8b)

The adhesive layer 8b is formed of a conductive adhesive which is formed by adding conductive fillers to adhesive resin. The shield printed wiring board is formed in such a way that a shield film is pasted onto a printed wiring board which includes a base member on which a ground wiring pattern and a signal wiring pattern are formed and an insulating film which is stacked onto the base member and which exposes at least a part of the ground wiring pattern, and thermal pressing is performed. Because the shield film 1 has the adhesive layer 8b at the surface where the shield film 1 is pasted onto the printed wiring board, the adhesive layer 8b is embedded in the part of the insulating film where the ground wiring pattern is exposed at the time of the thermal pressing. As such, the ground circuit of the printed wiring board is electrically connected with the metal layer 8a with certainly, on account of the adhesive layer 8b. The adhesive layer 8b may not be formed of a conductive adhesive, and may be formed of non-conductive adhesive resin.

Examples of the adhesive resin include thermoplastic resin such as polystyrene-based, vinyl acetate-based, polyester-based, polyethylene-based, polypropylene-based, polyamide-based, rubber-based, and acryl-based, and thermosetting resin such as phenol-based, epoxy-based, urethane-based, melamine-based, and alkyd-based. When heat resistance is not particularly required, polyester-based thermoplastic resin is preferred because it is not restricted in storage conditions or the like. When heat resistance or better flexibility is required, epoxy-based thermosetting resin is preferred on account of its high reliability.

Examples of the conductive fillers include carbon, silver, copper, nickel, solder, aluminum, silver-coated copper fillers formed by plating copper powder with silver, fillers formed by metal-plating resin balls, glass beads, or the like, and a mixture of such fillers. Silver is expensive, copper is not reliable in heat resistance, aluminum is not reliable in moisture resistance, and it is difficult by solder to obtain good conductivity. For these reasons, one of silver-coated copper fillers and nickel fillers which are relatively inexpensive, good in conductivity, and highly reliable is preferable.

As the conductive adhesive, anisotropic conductive adhesive in which the amount of conductive fillers is reduced may be used. When the anisotropic conductive adhesive is used as the conductive adhesive, the thickness of the film is reduced as compared to cases where isotropic conductive adhesive is used, and good flexibility is obtained because of the amount of the conductive fillers is small. In addition to the above, the isotropic conductive adhesive may be used as the conductive adhesive. When the isotropic conductive adhesive is used as the conductive adhesive, the ground connection to the ground circuit or the like is achieved and an electromagnetic wave shielding effect is obtained only by providing a conductive adhesive layer formed of the isotropic conductive adhesive. As such, the conductive adhesive layer is able to function as both a shield layer and an adhesive layer. The metal layer may be omitted in this case.

When the adhesive layer 8b is formed of the conductive adhesive, the mixing ratio of the conductive fillers such as metal fillers to the adhesive resin is, although depending on the shape of each filler or the like, preferably 10 parts by weight at the minimum to 100 parts by weight of the adhesive resin and 400 parts by weight at the maximum to 100 parts by weight of the adhesive resin.

When the adhesive layer 8b is formed of the anisotropic conductive adhesive, the mixing ratio of the conductive fillers to the adhesive resin is preferably 10 parts by weight at the minimum to 100 parts by weight of the adhesive resin, and 180 parts by weight at the maximum to 100 parts by weight of the adhesive resin. When the adhesive layer 8b is formed of the isotropic conductive adhesive, the mixing ratio of the conductive fillers to the adhesive resin is preferably 150 parts by weight at the minimum to 100 parts by weight of the adhesive resin and 250 parts by weight at the maximum to 100 parts by weight of the adhesive resin.

When the silver-coated copper fillers are used as the conductive fillers, the lower limit of the mixing ratio is preferably 10 parts by weight to 100 parts by weight of the adhesive resin, and more preferably 20 parts by weight. The upper limit is preferably 400 parts by weight, and more preferably 150 parts by weight. When the mixing ratio of the silver-coated copper fillers exceeds 400 parts by weight, the adhesion property to the ground circuit is deteriorated, and the flexibility of the shield film 1 is deteriorated. In the meanwhile, when the mixing ratio is smaller than 10 parts by weight, the conductivity is significantly deteriorated.

When the nickel fillers are used as the conductive fillers, the lower limit of the mixing ratio is preferably 40 parts by weight to 100 parts by weight of the adhesive resin, and more preferably 100 parts by weight. The upper limit is preferably 400 parts by weight, and more preferably 350 parts by weight. When the mixing ratio of the nickel fillers exceeds 400 parts by weight, the adhesion property to the ground circuit is deteriorated, and the flexibility of the shield film 1 is deteriorated. In the meanwhile, when the mixing ratio is smaller than 40 parts by weight, the conductivity is significantly deteriorated.

The shape of each the conductive fillers such as metal fillers may be any one of spherical shape, needle-shape, fiber-shape, flake-shape, or dendrite shape.

The thickness of the adhesive layer 8b is preferably 3 to 25 μm irrespective of the use of the conductive adhesive. Not limited to this, the adhesive layer 8b may be thickened for the amount of the addition of the conductive fillers such as metal fillers. When no conductive filler is added, the adhesive layer 8b can be thinned.

In this way, the shield film 1 has functions of known protective layers such as a function as a base when a conductive layer is stacked, because in the shield film 1 the insulating layer is formed of resin in which polymerization has proceeded so that the resin cure degree is 90% or higher. Because it is possible to form the shield film 1 which does not include a protective layer, the process for peeling the protective layer off from the shield film of the shield printed wiring board after the thermal pressing process is unnecessary, and hence cost reduction is achieved.

Furthermore, because the protective layer which is typically thicker than the total thickness of the insulating layer, the shield layer, and the adhesive layer and is about 50 μm thick is unnecessary, cost incurred when, for example, the rolled shield film is stored or transported is reduced.

### (Method of Manufacturing Shield Printed Wiring Board 10)

The following will describe a method of manufacturing a shield printed wiring board 10 which employs the shield film 1 above.

### (Shield Film Manufacturing Process)

To begin with, as described above, the shield film 1 including the insulating layer 7 made of resin in which polymerization has proceeded so that the resin cure degree is 90% or higher, the metal layer 8a stacked onto the insulating layer 7, and the adhesive layer 8b stacked onto the metal layer 8a is formed. The insulating layer 7 is preferably formed of film-shaped resin. However, even when the insulating layer 7 is formed by coating, the film which is used as the base during the coating can be peeled off at room temperatures before the thermal pressing is conducted, because the insulating layer 7 is in a cured state.

Now, a method of cutting the shield film 1 into a desired shape will be described.

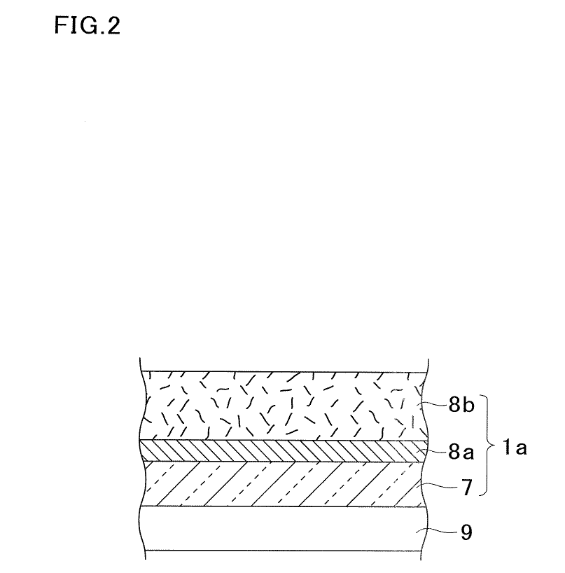

To be more specific, as shown in FIG. 2, a stacked body 1a which has the same stacked layers as the shield film which has not been cut into a desired shape is stacked onto the protective member 9. The stacked body 1a is stacked in such a way that the surface on the insulating layer 7 side is in contact with the protective member 9, but the stacked body 1a may be stacked in a different manner. For example, the stacked body 1 may be stacked in such a way that the surface on the adhesive layer 8b side is in contact with the protective member 9.

When stacking the protective member 9, a parting agent (release agent) may be used.

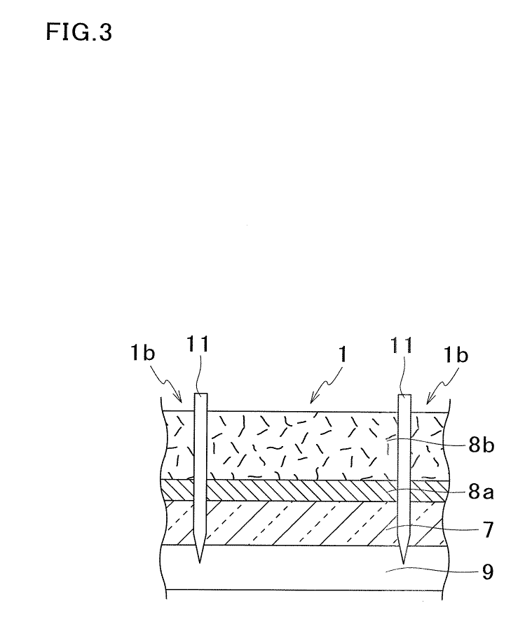

Thereafter, as shown in FIG. 3, half-cutting is performed such that the stacked body 1a is cut by using a cutter 11 from the adhesive layer 8b side, without fully cutting the protective member 9. In other words, the stacked body 1a is cut by the cutter 11 from the adhesive layer 8b side to the middle of the protective member 9. As a result, on the protective member 9, the stacked body 1a is separated into the shield film 1 and a peeled part 1b, and the peeled part 1b becomes peelable.

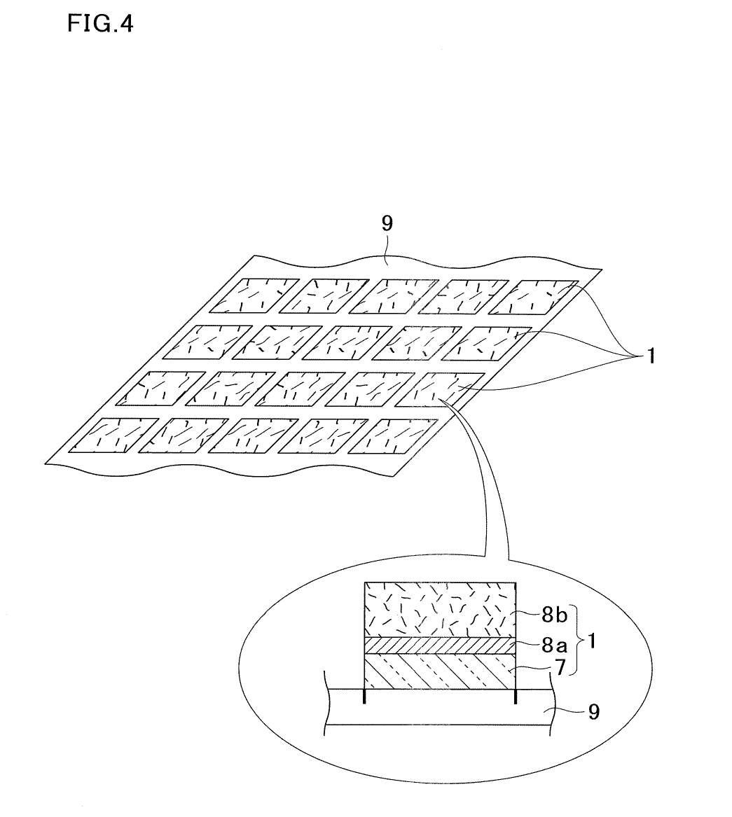

Then the peeled part 1b is peeled off, with the result that the shield film 1 which has been cut into the desired shape is stacked on the protective member 9, as shown in FIG. 4. As shown in FIG. 4, plural shield films 1 may be stacked on the protective member 9.

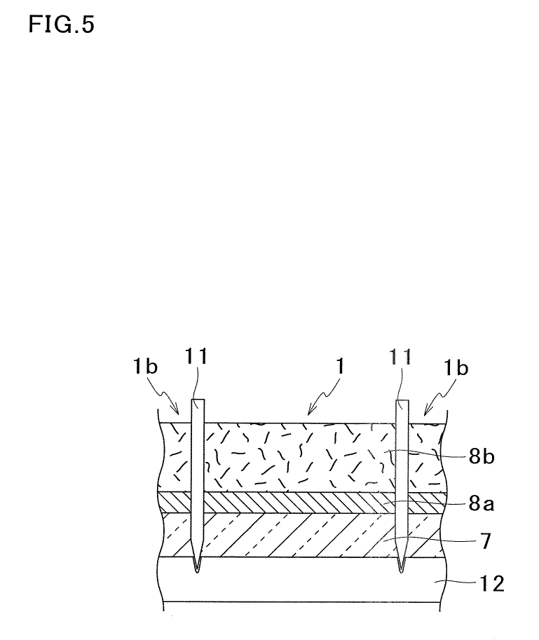

The process for cutting the shield film 1 into the desired shape is not limited to the above. For example, as shown in FIG. 5, the shield film 1 may be obtained in such a way that a surface on the insulating layer 7 side of the stacked body 1a is immovably mounted on a protective sheet 12 which is formed of sheet-shaped rubber, resin, or the like to be in contact with the protective sheet 12, and the stacked body 1a is cut into the desired shape by the cutter 11.

### (Shield Film Mounting Process and Thermal Pressing Process)

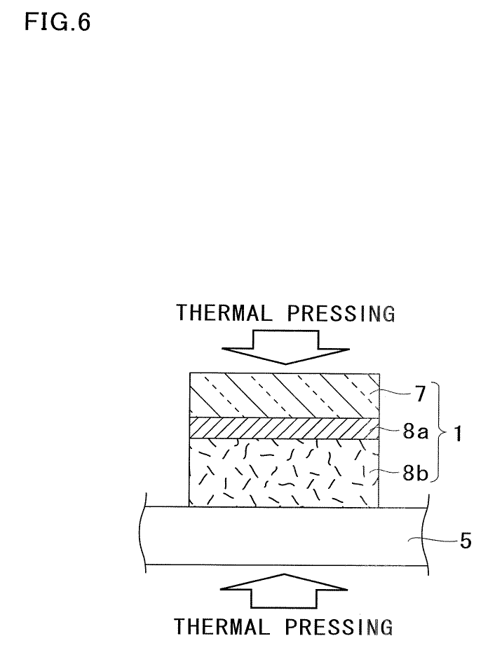

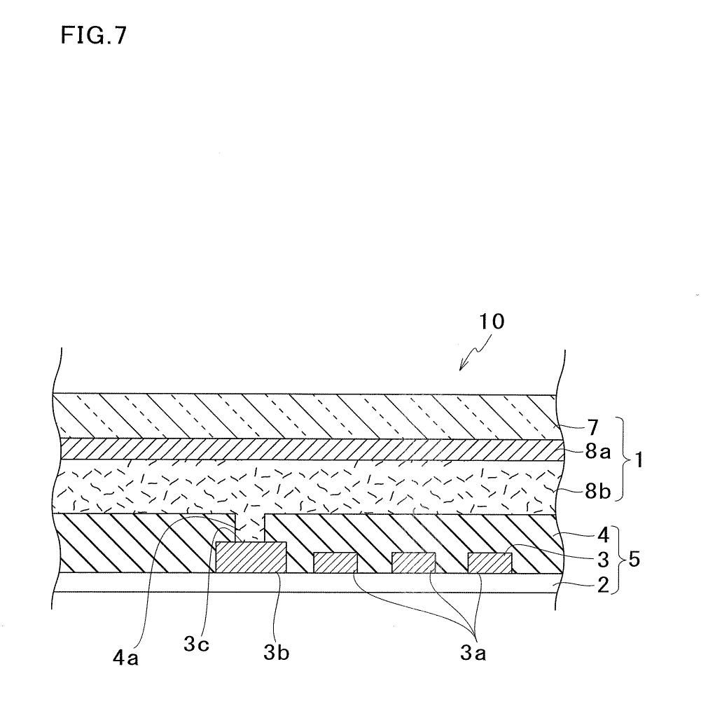

Subsequently, as shown in FIG. 6, the shield film 1 is peeled off from the protective member 9 on which the shield film 1 is stacked (see FIG. 4), and is mounted to a desired position on the printed board 5, and then the shield film 1 and the printed board 5 are subjected to thermal pressing. As a result, the shield printed wiring board 10 shown in FIG. 7 is manufactured. Because the shield film 1 is subjected to the thermal pressing while the insulating layer 7 is exposed, the insulating layer 7 is preferably formed of heat-resistant resin.

As described above, the insulating layer is made of resin in which polymerization has proceeded so that the resin cure degree is 90% or higher. The insulating layer therefore has a function of the known protective layers, and hence no protective layer for protecting the insulating layer is provided in the shield film 1 before the thermal pressing onto the printed wiring board. Furthermore, because it is also unnecessary to protect the insulating layer in the thermal pressing, it is possible to conduct the thermal pressing process without stacking a protective layer. As a result, it is unnecessary to perform a process for peeling the protective layer off from the shield film of the shield printed wiring board after the thermal pressing process, and hence cost reduction is achieved.

### (Configuration of Shield Printed Wiring Board 10)

The shield printed wiring board 10 is formed in such a way that the shield film 1 is pasted onto the printed board 5 including the base member 2 on which the wiring pattern 3 (the ground wiring pattern 3b and the signal wiring pattern 3a) is formed and the insulating film 4 which is stacked onto the base member 2 and exposes at least a part (non-insulating part 3c) of the ground wiring pattern 3b at an insulation removal part 4a, and thermal pressing is conducted.

Because the shield film 1 has the conductive adhesive layer 8b at the surface to which the printed board 5 is pasted, the adhesive layer 8b is embedded at a part where the ground wiring pattern 3b of the insulating film 4 is exposed at the time of the thermal pressing. With this, the non-insulating part 3c of the ground wiring pattern 3b is electrically connected with the metal layer 8a which functions as a shield layer, and hence the electromagnetic wave shielding property of the shield film is further improved.

In addition to the above, the shield film 1 is less than half as thick as known shield films, because the shield film 1 does not include the protective layer which is typically thicker than the total thickness of the insulating layer, the shield layer, and the adhesive layer. For this reason, the shield film 1 is easily deformed in accordance with the irregularities on the printed board 5 and the insulation removal part 4a, when the thermal pressing is conducted. To put it differently, in the shield printed wiring board 10, the adhesive layer 8b of the shield film 1 is deformed in accordance with not only the irregularities of the printed board 5 but also the insulation removal part 4a. The formation of a cavity at the adhesion interface between the insulation removal part 4a and the adhesive layer 8b is therefore prevented. With the use of the shield film 1 above, the embeddedness of the adhesive layer 8b in the printed board 5 is improved in the shield printed wiring board 10.

### REFERENCE SIGNS LIST

1 SHIELD FILM
1a STACKED BODY
1b PEELED PART
2 BASE MEMBER
3 WIRING PATTERN
3a SIGNAL WIRING PATTERN
3b GROUND WIRING PATTERN
3c NON-INSULATING PART
4 INSULATING FILM
4a INSULATION REMOVAL PART
5 PRINTED BOARD
7 INSULATING LAYER
8a METAL LAYER
8b ADHESIVE LAYER
9 PROTECTIVE MEMBER
10 SHIELD PRINTED WIRING BOARD
11 CUTTER

1. A method of manufacturing a shield printed wiring board, comprising the steps of:
forming a shield film which includes an insulating layer formed of resin in which polymerization has proceeded so that a resin cure degree is 90% or higher, a shield layer stacked onto the insulating layer, and an adhesive layer stacked onto the shield layer;
mounting the shield film on a printed board; and
thermally pressing the shield film and the printed board onto each other.

2. The method according to claim 1, wherein, the step of forming the shield film includes:
a half-cutting process for cutting, from the adhesive layer side, the shield film which is stacked onto the protective member such that a surface on the insulating layer side of the shield film is in contact with the protective member, without fully cutting the protective member; and
a process for peeling the shield film, which has been cut, off from the protective member.

3. The method according to claim 1, wherein, the step of forming the shield film includes
a cutting process for cutting the shield film which is mounted on a protective sheet so that a surface on the insulating layer side of the shield film is in contact with the protective sheet.

4. The method according to claim 1, wherein, the insulating layer is formed to be film-shaped.

5. The method according to claim 1, wherein, the insulating layer is formed of heat-resistant resin.

6. The method according to claim 1, wherein, the insulating layer is formed to be 2 μm to 25 μm in thickness.

7. A shield film comprising:
an insulating layer formed of resin in which polymerization has proceeded so that a resin cure degree is 90% or higher;
a shield layer stacked onto the insulating layer; and
an adhesive layer stacked onto the shield layer.

8. The shield film according to claim 7, wherein, the insulating layer is formed to be film-shaped.

9. The shield film according to claim 7, wherein, the insulating layer is formed of heat-resistant resin.

10. The shield film according to claim 7, wherein, the insulating layer is formed to be 2 μm to 25 μm in thickness.

11. A shield printed wiring board formed by thermally pressing the shield film of claim 7 and a printed wiring board onto each other.
